(19) United States
(12) Patent Application Publication
(10) Pub. No.: US 2025/0293082 A1
(43) Pub. Date: Sep. 18, 2025

(54) METHOD AND SYSTEM OF ARRANGING PATTERNS OF SEMICONDUCTOR DEVICE

(71) Applicant: TAIWAN SEMICONDUCTOR MANUFACTURING COMPANY LTD., HSINCHU (TW)

(72) Inventors: CHENG-YU LIN, HSINCHU COUNTY (TW); CHI-YU LU, NEW TAIPEI CITY (TW); CHIH-LIANG CHEN, HSINCHU CITY (TW); LI-CHUN TIEN, TAINAN CITY (TW); LEE-CHUNG LU, TAIPEI (TW); YUNG-CHIN HOU, TAIPEI (TW); GUO-HUEI WU, TAINAN CITY (TW); WEI-CHENG LIN, TAICHUNG CITY (TW); JIANN-TYNG TZENG, HSINCHU (TW)

(21) Appl. No.: 18/602,066

(22) Filed: Mar. 12, 2024

(51) Int. Cl. H01L 21/768; H01L 21/027; H01L 21/033; H01L 21/8234; H01L 29/66

(52) U.S. Cl. CPC H01L 21/76816; H01L 21/0274; H01L 21/0334; H10D 64/017; H10D 84/0126; H10D 84/038

(57) ABSTRACT

A method and system of arranging patterns of a semiconductor device are provided. The method includes: generating a plurality of active region layout patterns; generating a plurality of gate region layout patterns; and generating a plurality of dummy gate region layout patterns, and generating a plurality of cut feature layout patterns. The plurality of active region layout patterns, the plurality of cut feature layout patterns, the plurality of gate region layout pattern, and the plurality of dummy gate region layout patterns exhibit a plurality of units repeating periodically along at least one of the first direction, the second direction, or both.

### BACKGROUND

Industry requirements for decreased size in integrated circuits (ICs) have resulted in smaller devices which consume less power yet provide more functionality at higher speeds. The miniaturization process has also resulted in stricter design and manufacturing specifications as well as reliability challenges. Various electronic design automation (EDA) tools generate, optimize, and verify standard cell layout designs for integrated circuits while ensuring that the standard cell layout design and manufacturing specifications are met.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a flowchart of a method for manufacturing a semiconductor device according to various aspects of the present disclosure.

FIG. 2 is a flowchart of a method for manufacturing a semiconductor device according to various aspects of the present disclosure.

FIG. 3A illustrates a layout of a semiconductor device according to various aspects of the present disclosure.

FIG. 3B illustrates a layout of a semiconductor device according to various aspects of the present disclosure.

FIG. 3C illustrates a cross-sectional view along line A-A′ of the semiconductor device as shown in FIG. 3B according to various aspects of the present disclosure.

FIG. 4A illustrates a layout of a semiconductor device according to various aspects of the present disclosure.

FIG. 4B illustrates a layout of a semiconductor device according to various aspects of the present disclosure.

FIG. 5A illustrates a layout of a semiconductor device according to various aspects of the present disclosure.

FIG. 5B illustrates a layout of a semiconductor device according to various aspects of the present disclosure.

FIG. 6 is a flowchart of a method for manufacturing a semiconductor device according to various aspects of the present disclosure.

FIG. 7 illustrates layouts of semiconductor devices according to various aspects of the present disclosure.

FIG. 8 illustrates layouts of semiconductor devices according to various aspects of the present disclosure.

FIG. 9 illustrates layouts of semiconductor devices according to various aspects of the present disclosure.

FIG. 10 is a flowchart of a method for manufacturing a semiconductor device according to various aspects of the present disclosure.

FIG. 11 illustrates a layout of a semiconductor device according to various aspects of the present disclosure.

FIG. 12 illustrates a layout of a semiconductor device according to various aspects of the present disclosure.

FIG. 13 illustrates a layout of a semiconductor device according to various aspects of the present disclosure.

FIG. 14 is a flowchart of a method for manufacturing a semiconductor device according to various aspects of the present disclosure.

FIG. 15 illustrates a layout of a semiconductor device according to various aspects of the present disclosure.

FIG. 16 is a flowchart of a method for manufacturing a semiconductor device according to various aspects of the present disclosure.

FIG. 17A illustrates a layout of a semiconductor device according to various aspects of the present disclosure.

FIG. 17B illustrates a perspective view of a semiconductor device according to various aspects of the present disclosure.

FIG. 18 is a block diagram of a system of designing a semiconductor device, in accordance with some embodiments.

FIG. 19 is a block diagram of a semiconductor device manufacturing system, and a semiconductor device flow associated therewith, in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

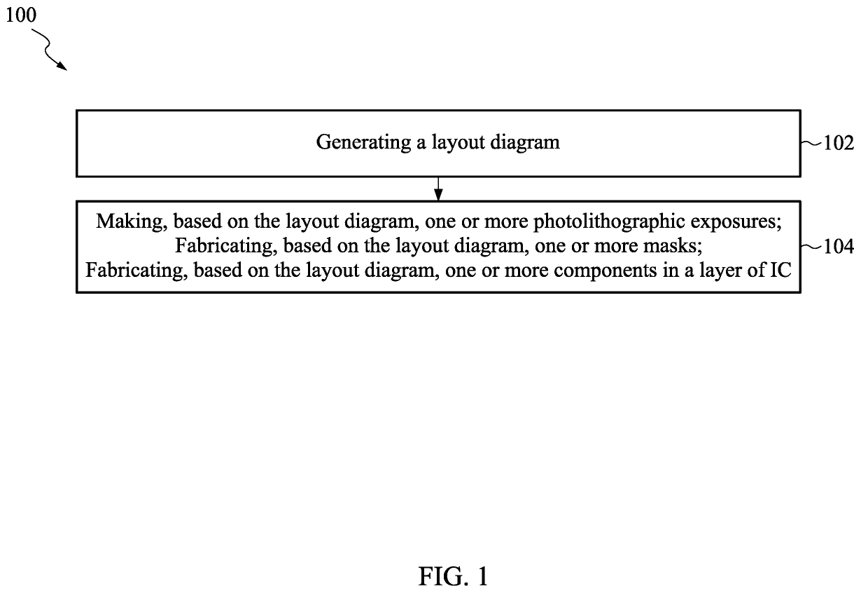

FIG. 1 illustrates a method 100 of manufacturing a semiconductor device, in accordance with some embodiments. In some embodiments, method 100 includes operations 102 and 104.

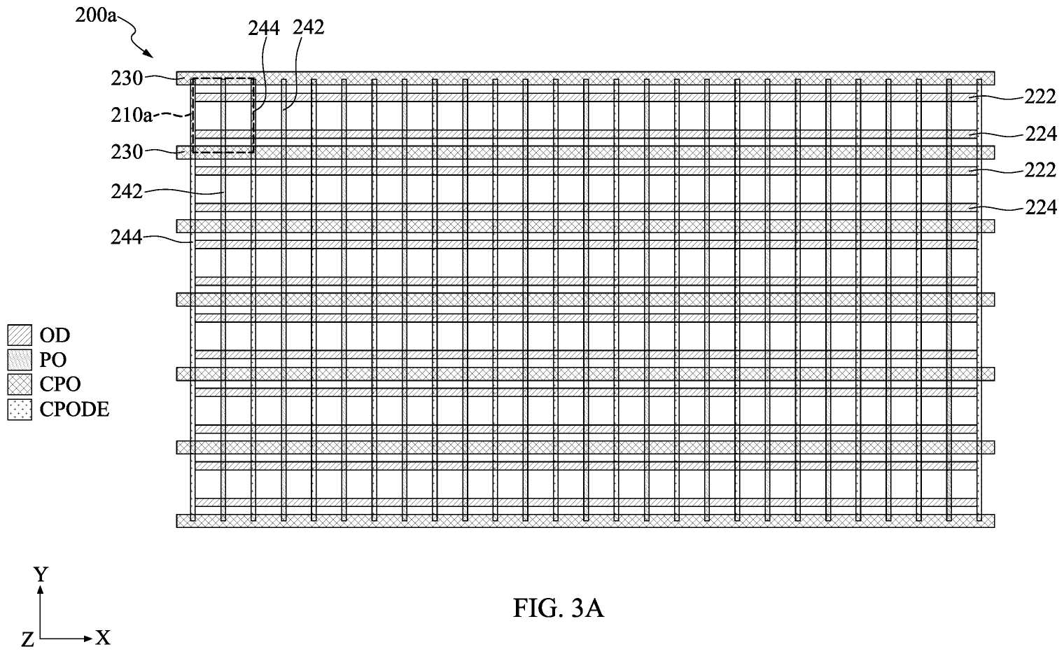

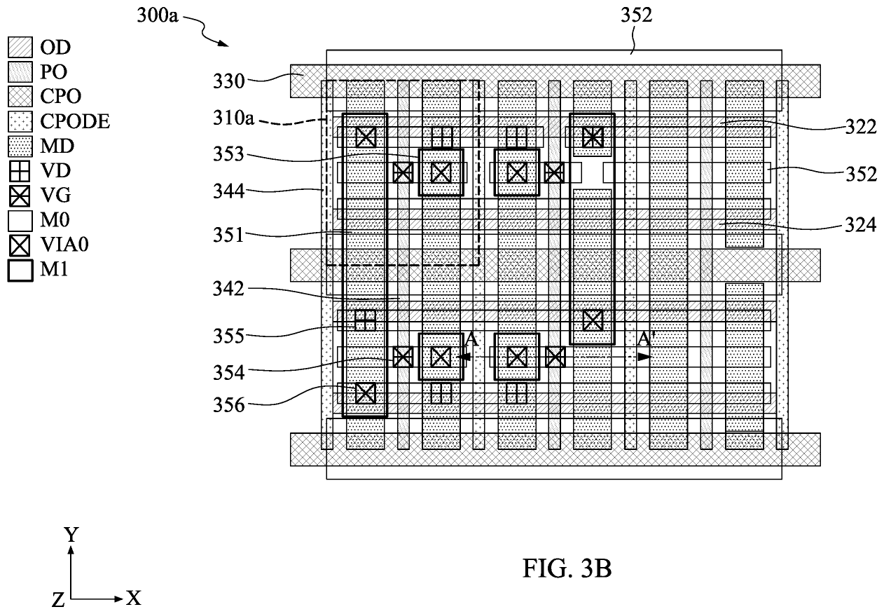

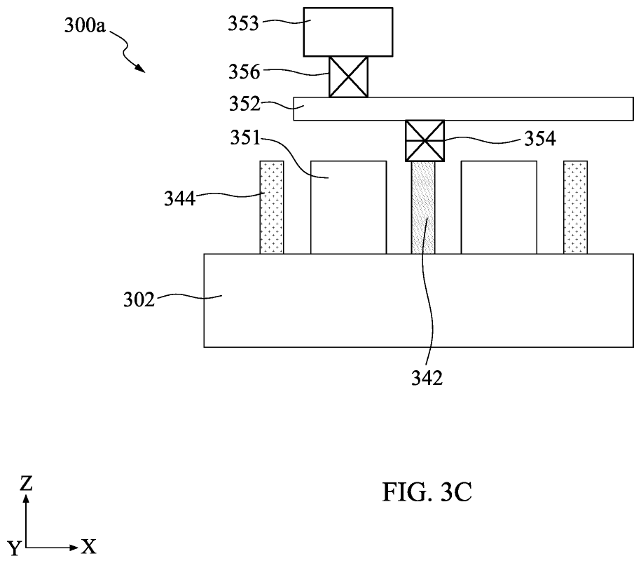

The method begins with operation 102 in which a layout diagram is generated. The layout diagram is discussed in more detail as follows with respect to FIGS. 3A, 4A, 5A, 7-9, 10-12, 13, 15 and 17A. More specifically, FIGS. 3A, 4A, 5A, 7-9, 10-12, 13, 15 and 17A illustrate how to produce a regular pattern which facilitates manufacturing processes and/or miniaturization of a semiconductor device.

The method 100 continues with operation 104: based on the layout diagram, in which at least one of (A) one or more photolithographic exposures are made or (B) one or more semiconductor masks are fabricated or (C) one or more components in a layer of a semiconductor device are fabricated.

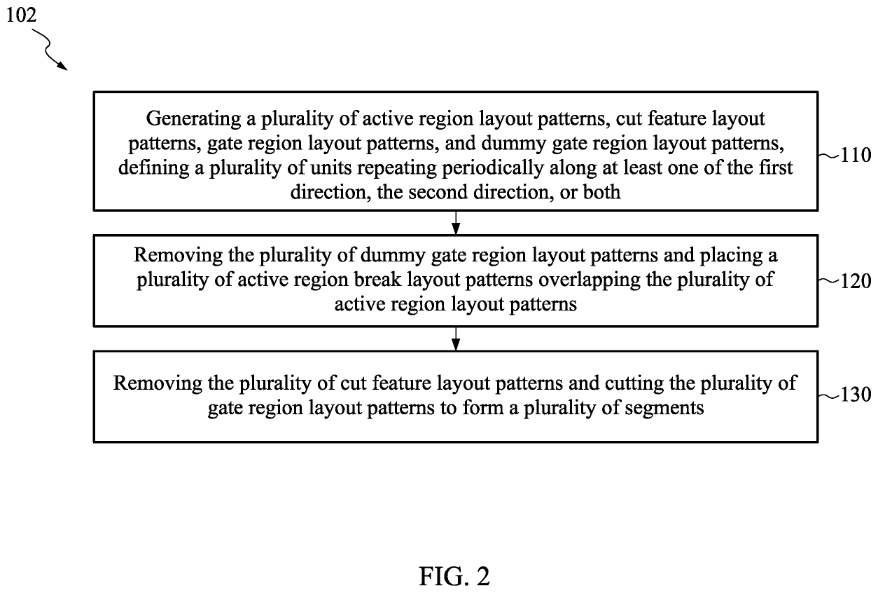

FIG. 2 is a flowchart of a method for generating regular layouts according to various aspects of the present disclosure. In some embodiments, operation 102 includes operations 110, 120, and 130. FIGS. 3A, 4A, and 5A illustrate regular layouts based on operations 110, 120, and 130, respectively.

Referring to FIG. 2, operation 102 begins with operation 110: generating a plurality of active region layout patterns, cut feature layout patterns, gate region layout patterns, and dummy gate region layout patterns, defining a plurality of units repeating periodically along at least one of the first direction, the second direction, or both.

FIG. 3A illustrates a layout 200a generated by operation 110. In some embodiments, the layout 200a includes a plurality of units 210a. In some embodiments, the unit 210a repeats periodically along at least one of the X direction, the Y direction, or both to define or exhibit the layout 200a. In some embodiments, each of the unit 210a 200a includes or is made of active region layout patterns 222 and 224, a cut feature layout pattern(s) 230, a gate region layout pattern(s) 242, and a dummy gate region layout pattern(s) 244.

Each of the active region layout patterns 222 and 224 extends along the X direction and can correspond to an active region of a semiconductor device. In some embodiments, each of the active region layout patterns 222 and 224 includes one or more fin structures for forming, for example, a fin field-effect transistor (FinFET). In some other embodiments, each of the active region layout patterns 222 and 224 may include one or more nanosheet structures. Each of the active region layout patterns 222 and 224 may correspond to an oxide definition layer (also referred to as “OD”) of a semiconductor device. Depending on requirements of the design, each of the active region layout patterns 222 and 224 may correspond to an active region of an n-type metal oxide semiconductor field effect transistor (NMOS) device or PMOS device.

Each of the gate region layout patterns 242 extends along the Y direction and can correspond to a gate structure (or gate stack) of a semiconductor device. The gate region layout pattern 242 may also be referred to as “PO” in some embodiments.

Each of the dummy gate region layout patterns 244 extends along the Y direction and can correspond to a dummy gate (or dummy gate stack) of a semiconductor device. In some embodiments, the dummy gate region layout pattern 244 corresponds to a non-functional conductive structure or a non-functional insulative structure of a semiconductor device. In some embodiments, the dummy gate region layout pattern 244 corresponds to a cut poly on OD edge layer (also referred to as “CPODE”) of a semiconductor device.

Each of the cut feature layout patterns 230 extends along the X direction and can be configured to cut the gate region layout pattern 242 and/or dummy gate region layout pattern 244. The cut feature layout pattern 230 corresponds to a poly cut layer (also referred to as “CPO”) of a semiconductor device, in which a dielectric material(s) is filled.

In this embodiment, the layout of the active region layout patterns 222 and 224, cut feature layout pattern 230, gate region layout pattern 242, and dummy gate region layout pattern 244 are fixed, which thereby defines or exhibits a regular layout. For example, each of the gate region layout patterns 242 has the same profile (e.g., the length or pattern); each of the dummy gate region layout patterns 244 has the same profile (e.g., the length or pattern); each of the cut feature layout patterns 230 has the same profile (e.g., the length or pattern). In this embodiment, other layout patterns, such as conductive feature layout patterns (or metal-to-device (MD) contact), are not fixed. In a comparative example, the layout patterns of OD, PO, CPO, and CPODE are not fixed and have multiple patterns (or length). Such variations may cause the features (e.g., gate stacks) to have different profiles and/or topographies. In this condition, gate stacks with different profiles produce a nonuniform environment, which makes other elements have an undesired variation of their profiles. In this embodiment, the layout patterns of OD, PO, CPO, and CPODE define or exhibit a regular pattern and thus, the semiconductor device based on this layout can produce a relatively uniform environment. Therefore, the profiles of other elements can be free of influence resulting from topographies of OD, PO, CPO, and CPODE, which facilitates miniaturization of a semiconductor device.

Referring to FIGS. 3B and 3C, FIG. 3B illustrates a layout of a semiconductor device 300a to which the layout 200a is applicable, and FIG. 3C is a cross-sectional view along line A-A′ of FIG. 3B. The semiconductor device 300a includes a substrate 302 as shown in FIG. 3C. The substrate 302 may be a semiconductor substrate, such as a bulk semiconductor, a semiconductor-on-insulator (SOI) substrate, or the like, which may be doped (e.g., with a p type or an n type dopant) or undoped. The substrate 302 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 302 may have a multilayer structure, or the substrate 302 may include a multilayer compound semiconductor structure. Although not shown in FIG. 3C, it should be noted that the semiconductor device 300a includes an isolation region to define or separate active regions. The isolation region includes shallow recess isolation (STI) or other suitable structures.

In some embodiments, the semiconductor device 300a includes active regions 322 and 324. Each of the active regions 322 and 324 extends along the X direction. In some embodiments, each of the active regions 322 and 324 includes one or more fin structures for forming, for example, a FinFET. In some embodiments, the fins of the active regions 322 and 324 are patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins. In some embodiments, each of the active regions 322 and 324 may also be referred to as OD. In some embodiments, the layout pattern of the active regions 322 and 324 is the same as that of the active region layout patterns 222 and 224 as shown in FIG. 3A. Each of the active regions 322 and 324 may function as an active region of an NMOS device or a PMOS device.

The semiconductor device 300a includes gate stacks 342. Each of the gate stacks 342 extends along the Y direction. Each of the gate stacks 342 is disposed on the substrate 302. In some embodiments, the gate stack 342 includes a gate dielectric and a gate electrode over the gate dielectric. The gate dielectric layer may include silicon oxide, silicon nitride, silicon oxynitride, high-k dielectric materials, or combinations thereof. The high-k material may have a dielectric constant ranging from about 4 to about 10. In some embodiments, the high-k material includes metal oxide, such as ZrO₂, Gd₂O₃, HfO₂, BaTiO₃, Al₂O₃, LaO₂, TiO₂, Ta₂Os, Y₂O₃, STO, BTO, BaZrO, HfZrO, HfLaO, HfTaO, HfTiO, a combination thereof, or a suitable material. In alternative embodiments, the gate dielectric layer may optionally include a silicate such as HfSiO, LaSiO, AlSiO, a combination thereof, or a suitable material. In some embodiments, the gate electrode includes a metal-containing material such as titanium nitride, titanium oxide, tantalum nitride, tantalum carbide, cobalt, ruthenium, aluminum, tungsten, combinations thereof, or multi-layers thereof. In some embodiments, the gate stack 342 is formed by: (a) forming a sacrificed gate; (b) forming a dielectric layer to encapsulate sacrificed gate; (c) removing (e.g., etching) the sacrificed gate to form a trench; and (d) filling the trench with a gate dielectric material(s) and a gate electrode material(s). In some embodiments, the layout pattern of the gate stack 342 is the same as that of the gate region layout pattern 242 as shown in FIG. 3A. In some embodiments, the gate stack 342 may also be referred to as “PO.”

The semiconductor device 300a includes dummy gates 344. Each of the dummy gates 344 extends along the Y direction. In some embodiments, the dummy gate 344 is a dielectric structure that includes one or more dielectric materials (e.g., oxide, nitride, oxynitride, or other suitable materials) and functions as an electrical isolation structure. Accordingly, the dummy gate 344 is not a structure that is electrically conductive and thus does not function, e.g., as an active gate of a transistor. In some embodiments, the dummy gate 344 is based on a gate as a precursor. In some embodiments, the dummy gate 344 includes a conductor, a gate-insulator layer, (optionally) one or more spacers, or the like. In some embodiments, the layout pattern of the dummy gate 344 is the same as that of the dummy gate region layout pattern 244 as shown in FIG. 3A. In some embodiments, the dummy gate 344 may also be referred to as “CPODE.”

The semiconductor device 300a includes cut features 330. Each of the cut features 330 extends along the X direction. The cut feature 330 is configured to cut the gate stack 342. The removed portion of the gate stack 342 by the cut feature 330 may be filled with a dielectric material(s). In some embodiments, the layout pattern of the cut feature 330 is the same as that of the cut feature layout pattern 230 and active region layout pattern 224 as shown in FIG. 3A. In some embodiments, the cut feature 330 may also be referred to as “CPO.”

The semiconductor device 300a includes conductive features 351. Each of the conductive features 351 extends along the Y direction. In some embodiments, the conductive features 351 are arranged as source/drain (S/D) contacts that are electrically connected to the source regions and/or the drain regions. In some embodiments, the conductive features 351 are also referred to as metal diffusion (MD) conductive features.

The semiconductor device 300a includes conductive lines 352. Each of the conductive lines 352 extends along the X direction. The conductive line 352 is disposed over the gate stack 342 and/or conductive feature 351. The conductive line 352 is configured to be electrically connected to the gate stack 342 and/or conductive feature 351. The conductive line 352 includes tungsten, copper, ruthenium, iridium, nickel, osmium, rhodium, aluminum, molybdenum, cobalt, tantalum, alloys thereof, and combinations thereof. The conductive line 352 can also be referred to as a metal zero (M0) layer.

The semiconductor device 300a includes conductive lines 353. Each of the conductive lines 353 extends along the Y direction. The conductive line 353 is disposed over the conductive line 352. The conductive line 353 is configured to be electrically connected to the conductive line 352. In some embodiments, the material of the conductive line 353 is the same as or similar to that of the conductive line 352. The conductive line 353 can also be referred to as a metal first (M1) layer.

The semiconductor device 300a includes interconnection features 354, 355, and 356. The interconnection feature 354 is configured to electrically connect the gate stack 342 and the conductive line 352. The interconnection feature 354 can also referred to as “VG” via. The interconnection feature 355 is configured to electrically connect the conductive feature 351 and the conductive line 352. The interconnection feature 355 can also referred to as “VD” via. The interconnection feature 356 is configured to electrically connect the conductive lines 352 and 353. The interconnection feature 356 can also referred to as “V1” via.

In some embodiments, the semiconductor device 300a includes units 310a which include active regions 322 and 324, a cut feature(s) 330, a gate stack(s) 342, and a dummy gate(s) 344. In some embodiments, the unit 310a repeats periodically along at least one of the X direction, the Y direction, or both. In this embodiment, the layout patterns of OD, PO, CPO, and CPODE define or exhibit a regular pattern, and thus the profiles of other elements can be free of influence resulting from topographies of said features, which facilitates miniaturization of a semiconductor device.

Referring back to FIG. 2, operation 102 continues with operation 120: removing the plurality of dummy gate region layout patterns and placing a plurality of active region break layout patterns overlapping the plurality of active region layout patterns.

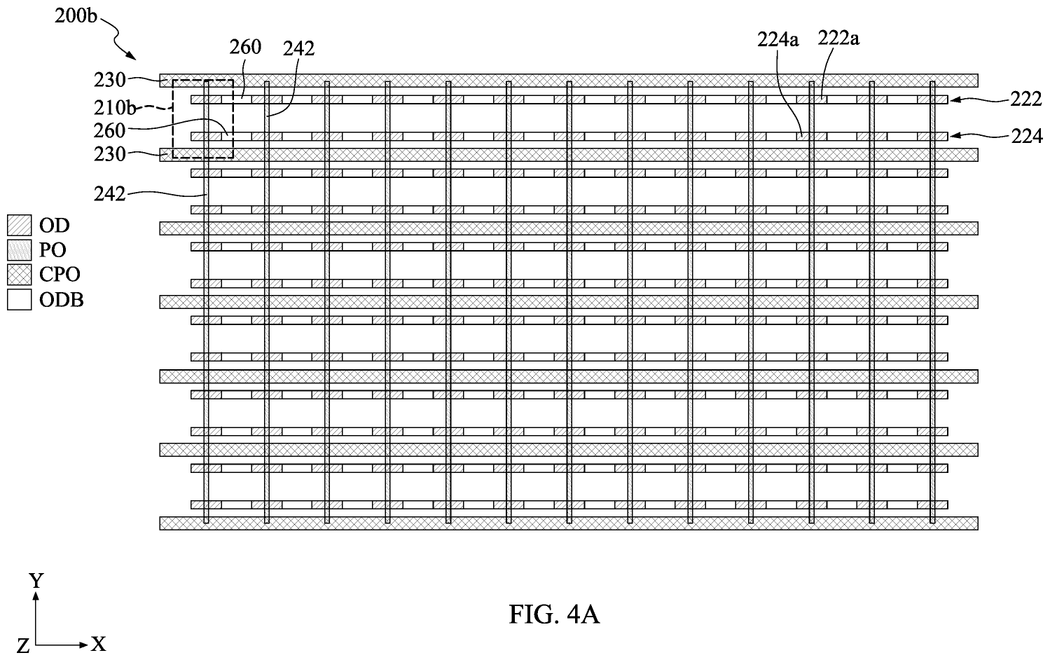

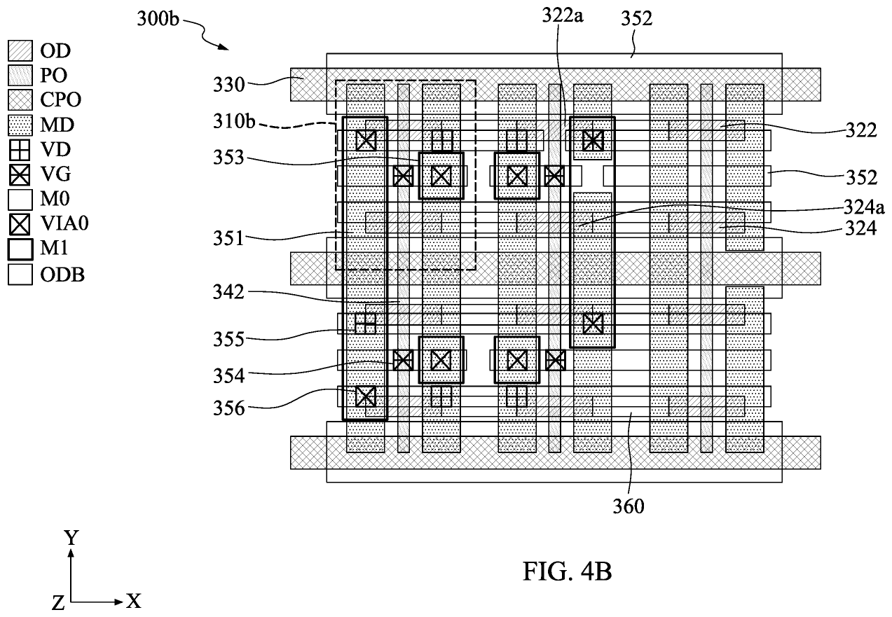

FIG. 4A illustrates a layout 200b generated by operation 120. In some embodiments, the dummy gate region layout patterns 244 as shown in FIG. 3A are removed. Further, the layout 200b includes active region break layout patterns 260. The active region break layout pattern 260 overlaps the active region layout patterns 222 or 224 along the Z direction. In some embodiments, each of the active region break layout patterns 260 is configured to disconnect, cut, or remove the active region layout patterns 222 or 224 to form segments 222a and 224a. In other embodiments, the active region break layout patterns 260 arranged along the Y direction can be connected and regarded as one active region break layout pattern.

In some embodiments, the layout 200b includes units 210b, which includes or is composed of active region layout patterns 222 and 224, the cut feature layout pattern(s) 230, the gate region layout pattern(s) 242, and the active region break layout pattern(s) 260. The unit 210b repeats periodically along at least one of the X direction, the Y direction, or both to define or exhibit the layout 200b.

Since the dummy gate region layout pattern 244 as shown in FIG. 3A has a regular pattern, the dummy gate region layout pattern 244 can be replaced by active region break layout pattern 260 to achieve disconnecting the active region layout patterns 222 or 224. In this embodiment, the mask for defining the pattern of the dummy gate can be replaced by the mask for defining the pattern of the active region break layout pattern 260. Since the dummy gates are omitted, the sacrificed gates to be replaced by the dummy gates can also be omitted. In this condition, the pitch of the sacrificed gates will be twice as much as that as shown in FIG. 3A, which facilitates the miniaturization of a semiconductor device.

Referring to FIG. 4B, it illustrates a semiconductor device 300b to which the layout 200b is applicable. The semiconductor device 300b is similar to the semiconductor device 300a. In some embodiments, the dummy gates 344 as shown in FIG. 3A are omitted. Further, the semiconductor device 300b includes active region disconnection features 360. In some embodiments, each of the active region disconnection features 360 is configured to disconnect, cut, or remove the active regions 322 or 324. The active region 322 includes segments 322a spaced apart from each other by the active region disconnection feature 360. The active region 324 includes segments 324a spaced apart from each other by the active region disconnection feature 360. In some embodiments, the active region disconnection feature 360 corresponds to a removed portion of the active region 322 or 324, which may be filled by a dielectric material(s). The active region disconnection feature 360 can also be referred to as an OD break (ODB) layer.

In some embodiments, the semiconductor device 300b includes units 310b which include the active regions 322 and 324, cut feature(s) 330, gate stack(s) 342, and active region disconnection feature(s) 360. In some embodiments, the unit 310b repeats periodically along at least one of the X direction, the Y direction, or both. In this embodiment, the layout patterns of the OD, PO, and CPO are fixed, which facilitates miniaturization of a semiconductor device.

Referring back to FIG. 2, operation 102 continues with operation 130: removing the plurality of cut feature layout patterns and cutting the plurality of gate region layout patterns to form a plurality of segments.

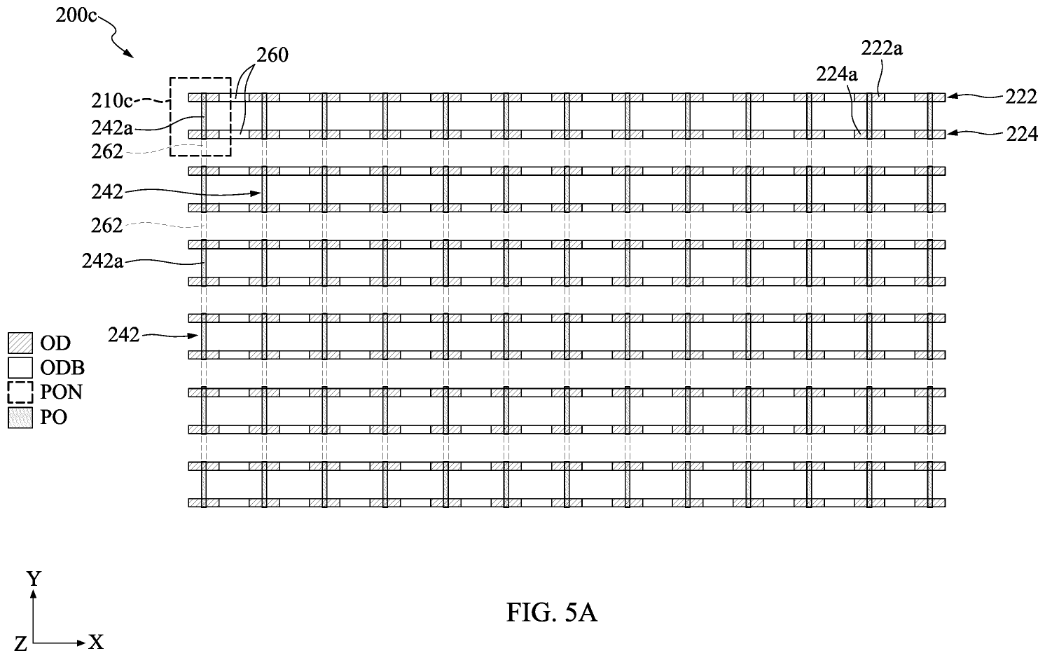

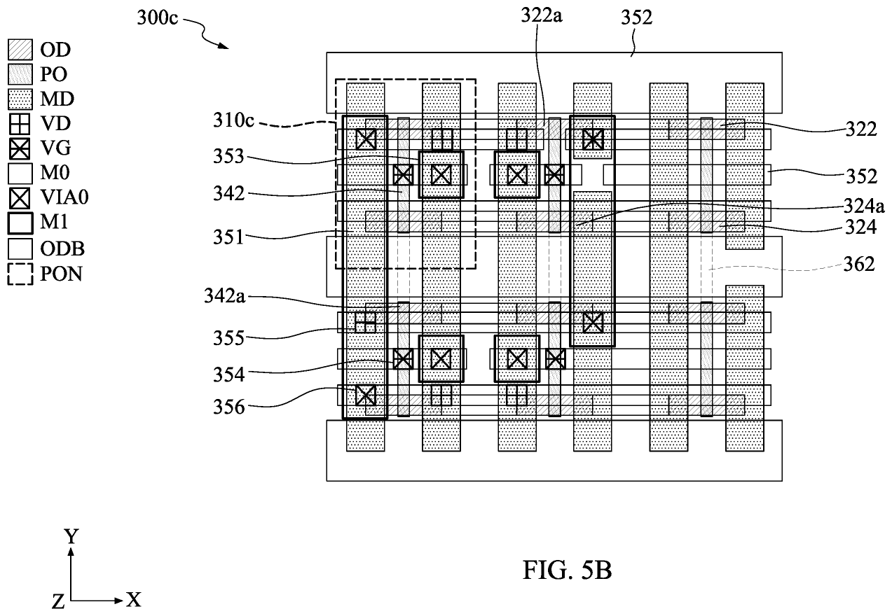

FIG. 5A illustrates a layout 200c generated by operation 130. In some embodiments, the cut feature layout patterns 230 as shown in FIG. 4A are removed. Further, the layout 200c includes gate region disconnection layout patterns 262. In some embodiments, each of the gate region disconnection layout patterns 262 is configured to disconnect, cut, or remove the gate region layout pattern 242 to form segments 242a.

In some embodiments, the layout 200c includes units 210c, which includes or is composed of the active layout patterns 222 and 224, gate region layout pattern(s), active region break layout pattern(s) 260, and gate region disconnection layout pattern(s) 262. The unit 210c repeats periodically along at least one of the X direction, the Y direction, or both to define or exhibit the layout 200c.

Since the cut feature layout patterns 230 as shown in FIG. 4B have a regular pattern, the cut feature layout patterns 230 can be replaced by the gate region disconnection layout patterns 262 to achieve disconnecting the gate region layout patterns. In this embodiment, the process for defining the cut feature layout pattern 230 may be replaced by one for defining the gate region disconnection layout pattern 262, which reduces the cost.

Referring to FIG. 5B, it illustrates a semiconductor device 300c to which the layout 200c is applicable. The semiconductor device 300c is similar to the semiconductor device 300b. In some embodiments, the cut features 330 as shown in FIG. 4B are omitted. Further, the semiconductor device 300c includes gate disconnection features 362. In some embodiments, each of the gate disconnection features 362 is configured to disconnect, cut, or remove the gate stack 342. The gate stack 342 includes segments 342a spaced apart from each other by the gate disconnection feature 362. In some embodiments, the gate disconnection feature 362 corresponds to a removed portion of the gate stack 342, which may be filled by a dielectric material(s). The gate disconnection feature 362 can also be referred to as a PO nature defined (PON) layer.

In some embodiments, the semiconductor device 300c includes units 310c which include the active regions 322 and 324, gate stack(s) 342, active region disconnection feature(s) 360, and gate disconnection feature(s) 362. In some embodiments, the unit 310c repeats periodically along at least one of the X direction, the Y direction, or both. In some conditions, the process for defining the CPO may have a greater cost. In this embodiment, the process for forming the CPO is replaced by one for forming the PON which has a lower cost requirement. As a result, the cost of manufacturing a semiconductor is reduced.

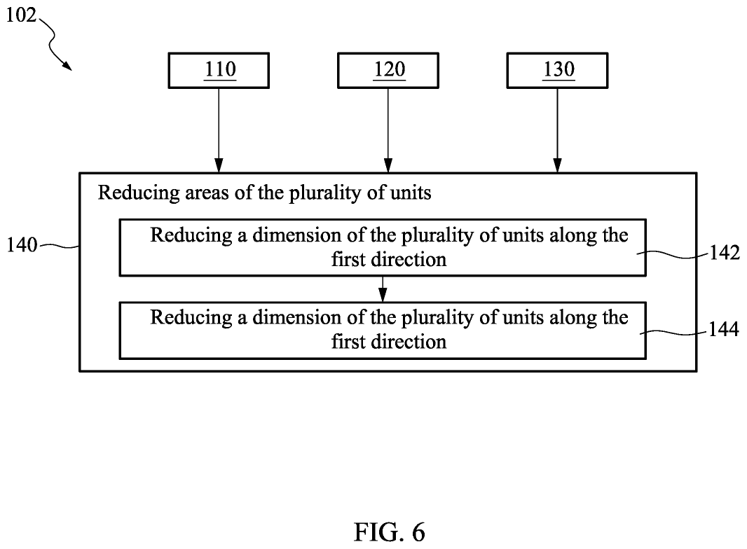

Referring to FIG. 6, each of operations 110, 120, and 130 can continue with operation 140: reducing areas of the plurality of units. Since each of the layouts 200a to 200c facilitates the miniaturization of a semiconductor device, the semiconductor device generated by the layouts 200a to 200c can be miniaturized. In some embodiments, operation 140 begins with operation 142: reducing a dimension (e.g., length and/or width) of the plurality of units along the first direction (e.g., the X direction). In some embodiments, operation 140 continues with operation 144: reducing a dimension (e.g., length and/or width) of the plurality of units along the second direction different from the first direction.

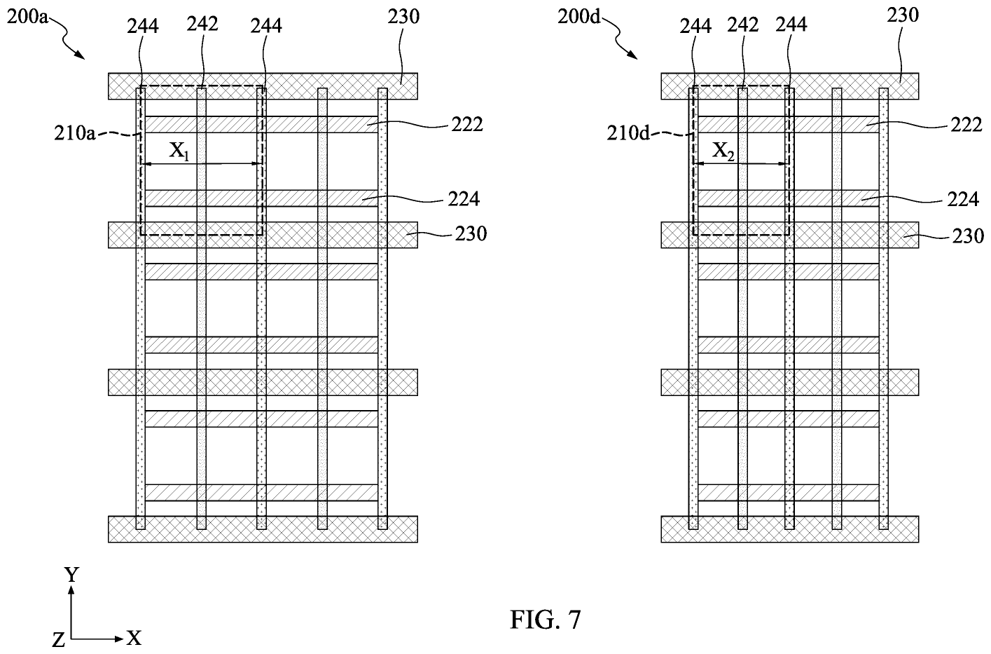

Referring to FIG. 7, it illustrates partial layouts of the layouts 200a and 200d which are miniaturized and generated by operation 142. The layout 200d has units 210d. The unit 210d repeats periodically along at least one of the X direction, the Y direction, or both. In some embodiments, the dimension of the unit 210d along the X direction can be reduced. In some embodiments, the pitch of the dummy gate region layout pattern 244 (or gate region layout pattern 242) can be reduced. For example, the pitch of the dummy gate region layout patterns 244 (or gate region layout patterns 242) of the layout 200a has a length X₁ along the X direction, and the pitch of the dummy gate region layout patterns 244 (or gate region layout patterns 242) of the layout 200d has a length X₂ along the X direction. In some embodiments, the ratio of the length X₂ to length X₁ is equal to or greater than 0.5 and less than 1, such as 0.5, 0.6, 0.7, 0.8, 0.9, or 0.99. The dimension of the layout 200d is reduced, which thereby results in a semiconductor device with a greater transistor density per unit area.

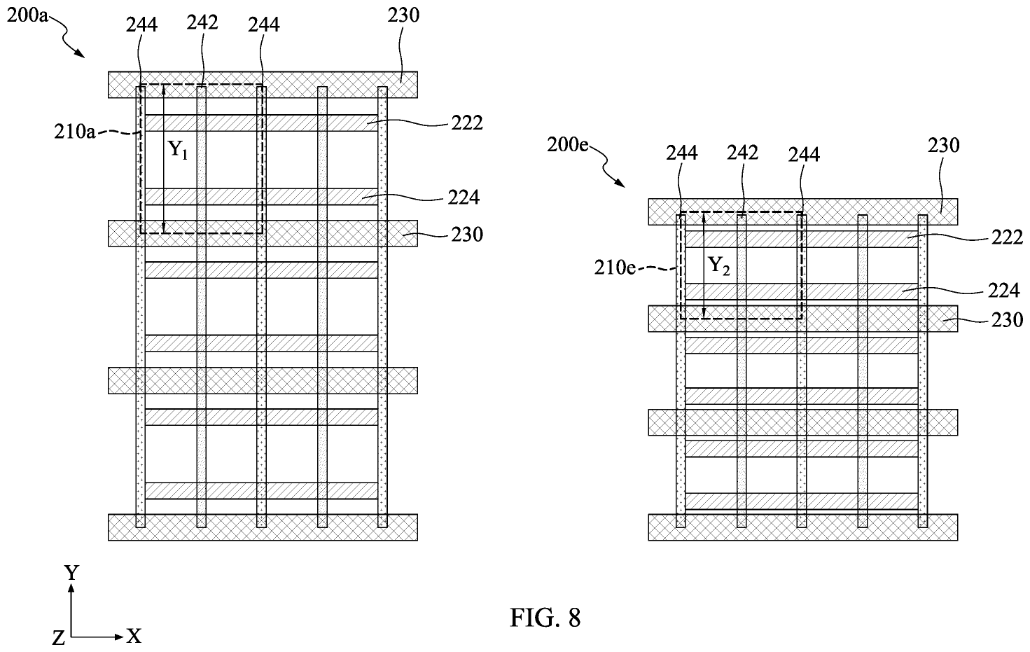

Referring to FIG. 8, it illustrates partial layouts of the layouts 200a and 200e which are miniaturized and generated by operation 142 in other embodiments. The layout 200e has units 210e. The unit 210e repeats periodically along at least one of the X direction, the Y direction, or both. In some embodiments, the dimension of the unit 210e along the Y direction can be reduced. In some embodiments, the pitch of the cut feature layout patterns 230 can be reduced. For example, the pitch of the cut feature layout patterns 230 of the layout 200a has a length Y₁ along the Y direction, and the pitch of the cut feature layout patterns 230 of the layout 200e has a length Y₂ along the Y direction. In some embodiments, the ratio of the length Y₂ to length Y₁ is equal to or greater than 0.5 and less than 1, such as 0.5, 0.6, 0.7, 0.8, 0.9, or 0.99. In some embodiments, the distance between the active region layout patterns 222 and 224 can be reduced. The dimension of the layout 200e is reduced, which thereby results in a semiconductor device with a greater transistor density per unit area.

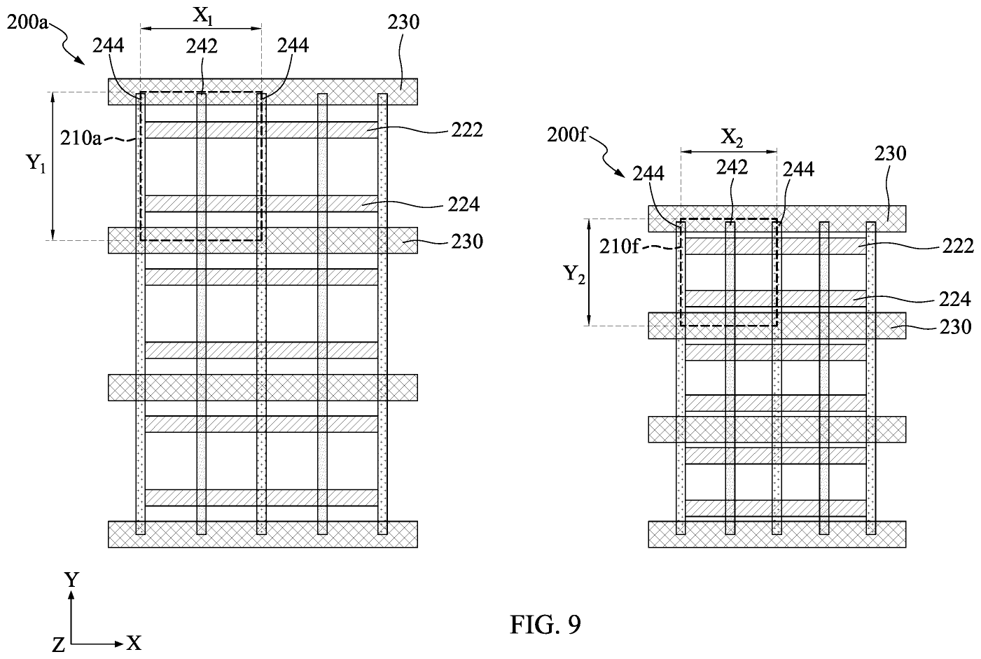

Referring to FIG. 9, it illustrates partial layouts of the layouts 200a and 200f. The layout 200f has units 210f. The unit 210f repeats periodically along at least one of the X direction, the Y direction, or both. In some embodiments, the dimensions of the unit 210f along the X direction and Y direction can be reduced. In this embodiment, the pitches of the cut feature layout patterns 230, gate region layout patterns 242, and dummy gate region layout patterns are reduced, which thereby results in a semiconductor device with a greater transistor density per unit area.

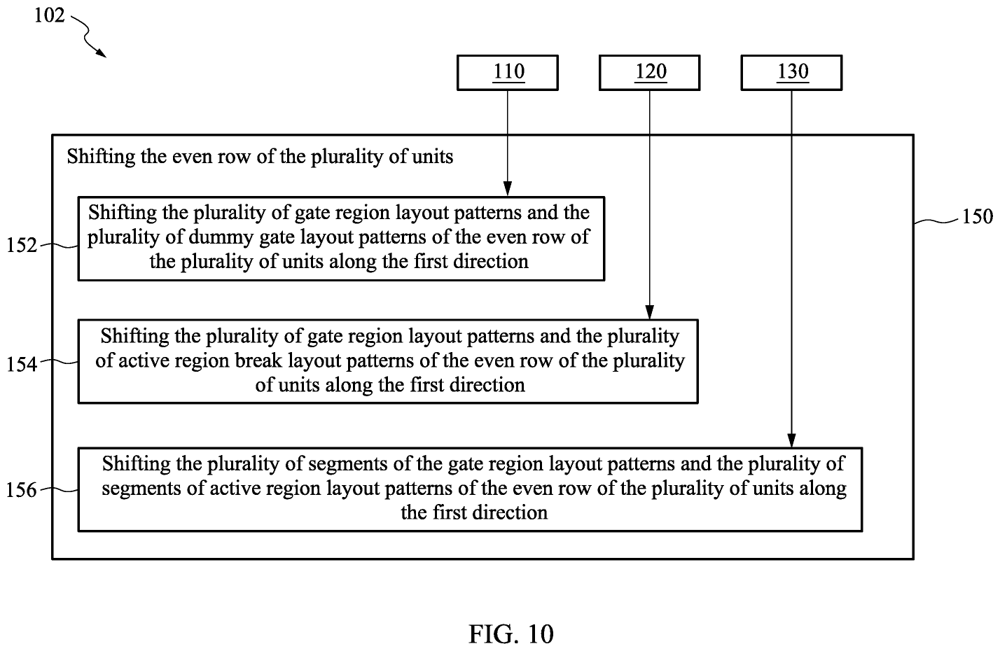

Referring to FIG. 10, each of operations 110, 120, and 130 can continue with operation 150: shifting the even rows (or odd rows) of the plurality of units. The units of the layout may be classified into the odd row (or first group) and the second row (or second group). In some embodiments, the first or second group of the units is shifted. In some embodiments, operation 150 includes operations 152, 154, and 156, each of which follows operation 110, 120, and 130, respectively.

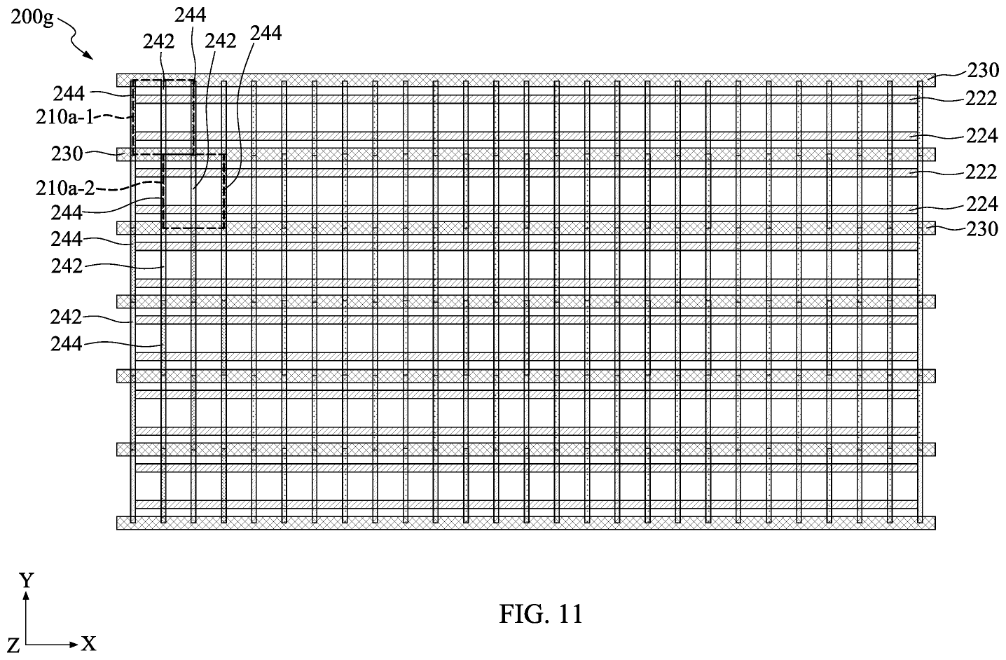

Referring to FIG. 11, it illustrates a layout 200g generated by operation 152: shifting the plurality of gate region layout patterns and the plurality of dummy gate layout patterns of the second group (or even row) of the plurality of units along the first direction.

In some embodiments, the even rows of the units 210a as shown in FIG. 3A can be shifted by 1 CPP (contacted poly pitch) along the X direction. In some embodiments, 1 CPP is equal to a distance between the gate region layout pattern 242 and the dummy gate region layout pattern 244 which abut. In some embodiments, 1 CPP is equal to a half of the pitch of the gate region layout patterns 242 (or dummy gate region layout patterns 244). In some embodiments, the gate region layout pattern 242 of the second group is shifted by 1 CPP. In some embodiments, the dummy gate region layout pattern 244 of the second group is shifted by 1 CPP. The layout 200g includes units 210a-1, and units 210a-2 are formed.

Each of units 210a-1 and 210a-2 includes or is composed of the active region layout patterns 222 and 224, the cut feature layout pattern(s) 230, the gate region layout pattern(s) 242, and the dummy gate region layout pattern(s) 244. The units 210a-1 are located at the odd rows (or first group), and the units 210a-2 are located at the even rows (or second group). In some embodiments, the gate region layout pattern 242 of the unit 210a-1 is aligned with or abuts the dummy gate region layout pattern 244 of the unit 210a-2 along the Y direction.

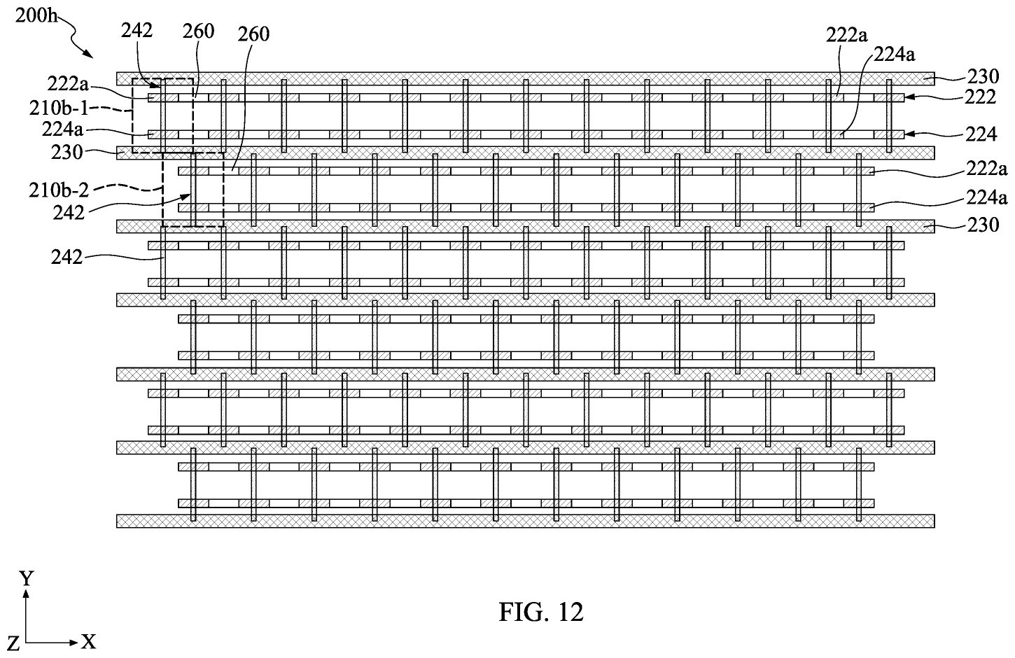

Referring to FIG. 12, it illustrates a layout 200h generated by operation 154: shifting the plurality of gate region layout patterns and the plurality of active region break layout patterns of the second group (or even row) of the plurality of units along the first direction.

In some embodiments, the even row (or second group) of the unit 210b as shown in FIG. 4A can be shifted by 1 CPP along the X direction. In some embodiments, the gate region layout pattern 242 of the second group is shifted by 1 CPP. In some embodiments, the active region break layout pattern 260 of the second group is shifted by 1 CPP. The layout 200h includes units 210b-1 and units 210b-2. The units 210b-1 are located at the odd row (or first group), and the units 210b-2 are located at the even row (or second group). Each of the units 210b-1 and 210b-2 includes or is composed of the active region layout patterns 222 and 224, cut feature layout pattern(s) 230, gate region layout pattern(s) 242, and active region break layout pattern(s) 260. The units 210b-1 are located at the odd rows (or first group), and the units 210b-2 are located at the even rows (or second group).

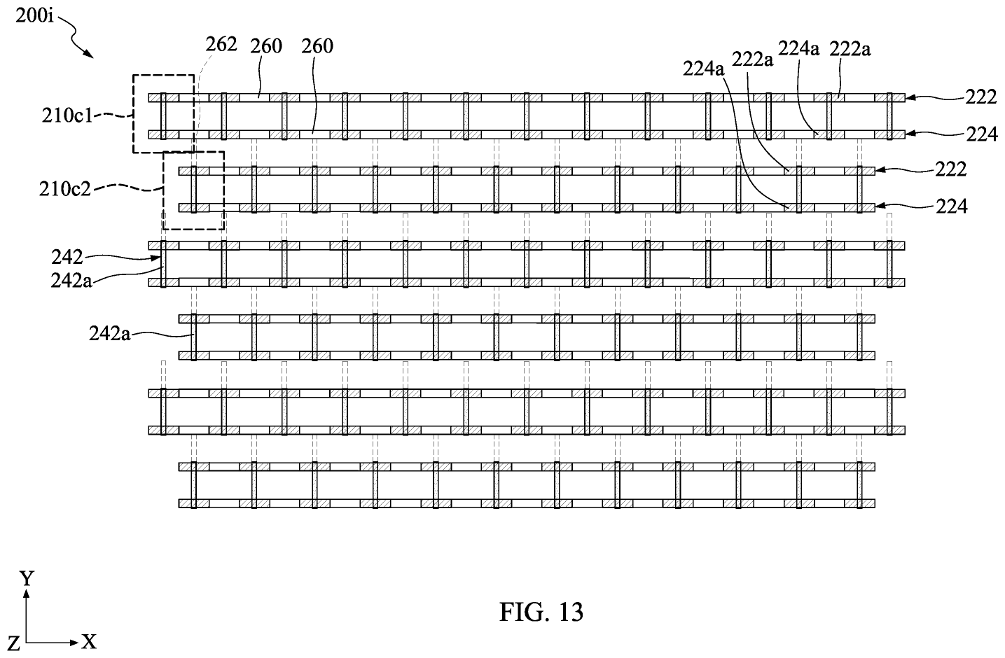

Referring to FIG. 13, it illustrates a layout 200i generated by operation 156: shifting the plurality of segments of the gate region layout patterns and the plurality of segments of active region layout patterns of the second group (or even row) of the plurality of units along the first direction.

In some embodiments, the even row of the unit 210c as shown in FIG. 5A can be shifted by 1 CPP along the X direction. In some embodiments, the segments 242a of the gate region layout pattern of the second group (or even row) are shifted by 1 CPP. In some embodiments, the gate region disconnection layout patterns 262 of the second group (or even) are shifted by 1 CPP. The layout 200i includes units 210c-1 and units 210c-2. The units 210c-1 are located at the odd row (or first group), and the units 210c-2 are located at the even row (or second group). Each of the units 210c-1 and 210c-2 includes or is composed of the active region layout patterns 222 and 224, gate region layout pattern(s) 242, active region break layout pattern(s) 260 and gate region disconnection layout pattern(s) 262.

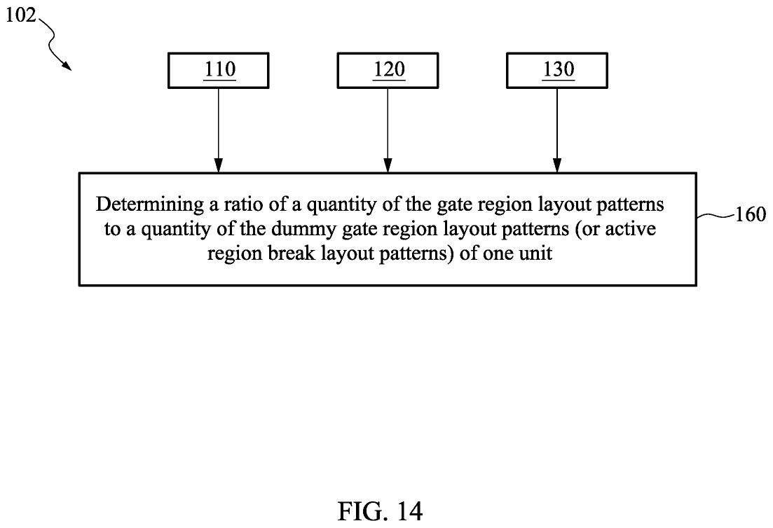

Referring to FIG. 14, each of operations 110, 120, and 130 can continue with operation 160: determining a ratio of the quantity of the gate region layout patterns to the quantity of the dummy gate region layout patterns (or active region break layout patterns) of one unit. In some embodiments, the ratio of the gate region layout patterns to the dummy gate region layout patterns (or active region break layout patterns) can be adjusted, controlled, or modified based on the design of circuits.

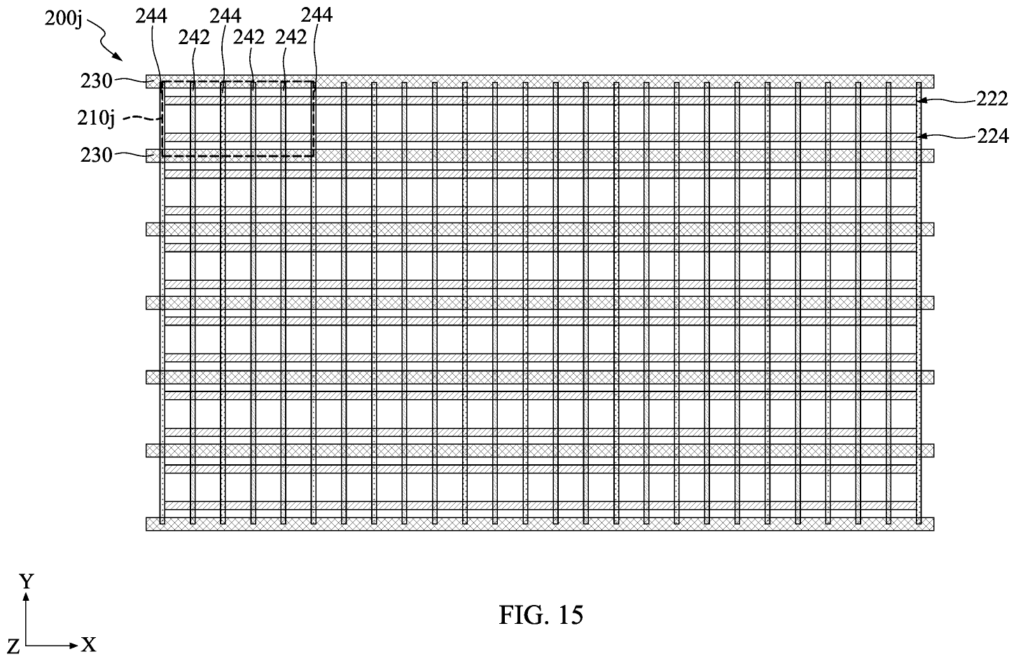

Referring to FIG. 15, it illustrates a layout 200j generated by operation 160. The layout 200j includes units 210j. The unit 210j repeats periodically along at least one of the X direction, the Y direction, or both. In some conditions, the ratio of the gate region layout pattern 242 to the dummy gate region layout pattern 244 is not 1:1. As shown in FIG. 15, the ratio of the gate region layout patterns 242 to the dummy gate region layout patterns 244 can be 3:2 or other suitable ratios, based on the design of circuits. In some embodiments, operation 160 can be followed by operation operations 140 and 150.

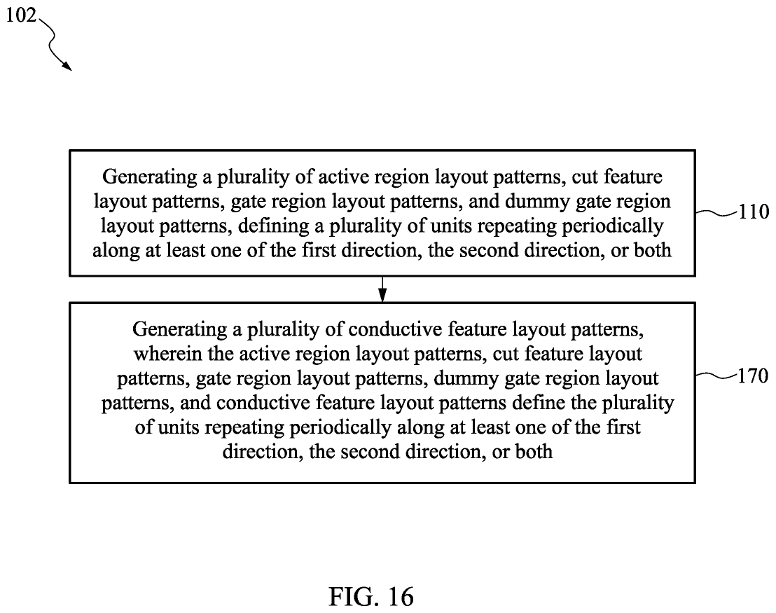

Referring to FIG. 16, operation 110 can continue with operation 170: generating a plurality of conductive feature layout patterns, wherein the active region layout patterns, cut feature layout patterns, gate region layout patterns, dummy gate region layout patterns, and conductive feature layout patterns define or exhibit the plurality of units repeating periodically along at least one of the first direction, the second direction, or both.

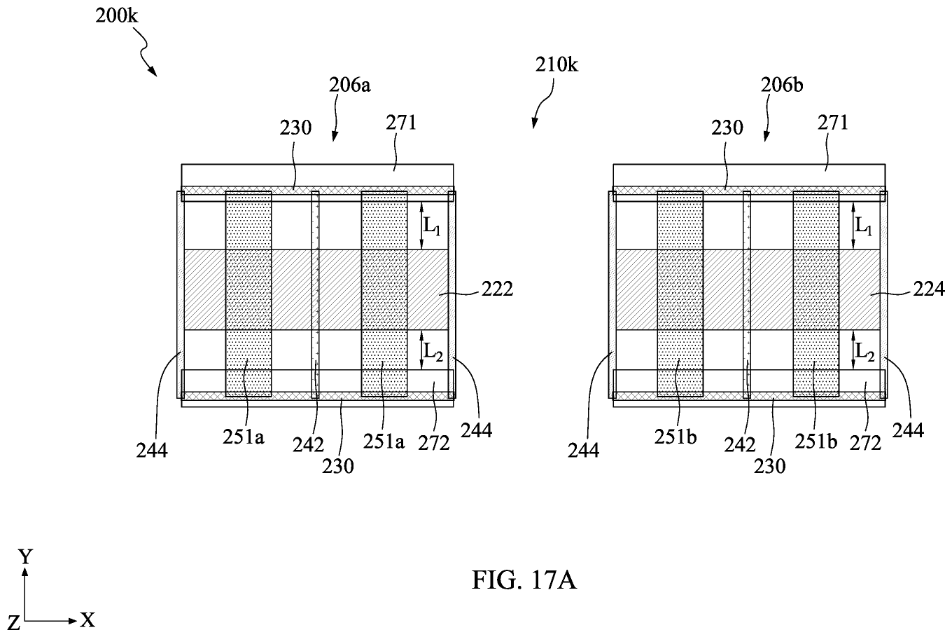

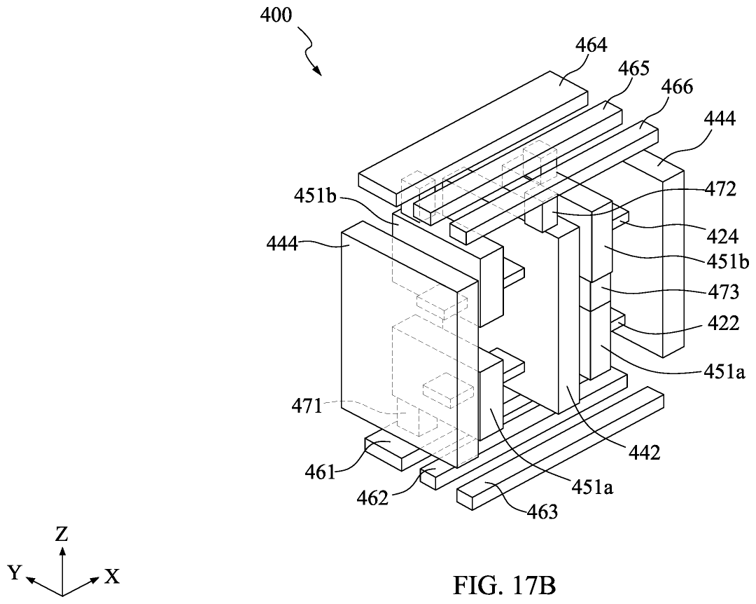

Referring to FIG. 17A, it illustrates a layout 200k generated by operation 170. In some embodiments, the layout 200k can be applicable to a complementary field-effect transistor (CFET), which involves vertically stacked active regions. The layout 200k includes parts 206a and 206b. The layout of the part 206a is located at a first elevation with respect to a substrate (e.g., the substrate 302 as shown in FIG. 3C), and the layout of the part 206b is located at a second elevation, with respect to a substrate (e.g., the substrate 302 as shown in FIG. 3C), greater than the first elevation. It should be noted that the part 206b overlaps the part 206a along the Z direction, and FIG. 17A illustrates the parts 206a and 206b individually for brevity. For example, the active region layout pattern 222 overlaps the active region layout pattern 224 along the Z direction. In this embodiment, the gate region layout pattern 242 further extends along the Z direction. The dummy gate region layout pattern 244 further extends along the Z direction. The cut feature layout pattern 230 further extends along the Z direction. In some embodiments, the layout 200k includes conductive region layout patterns 251a and conductive region layout patterns 251b spaced apart from the conductive region layout patterns 251a. The conductive region layout pattern 251a is located at the first elevation. The conductive region layout pattern 251b is located at the second elevation.

In some embodiments, the layout 200k further includes cut-conductive region layout patterns 271 and 272. The cut-conductive region layout patterns 271 and 272 may be located at opposite sides of the active region layout pattern 222 (or 224). In some embodiments, each of the cut-conductive region layout patterns 271 and 272 is configured to cut or disconnect the conductive region layout patterns 251a and/or 251b. In some embodiments, each of the cut-conductive region layout patterns 271 and 272 corresponds to a cut-MD layer (also referred to as “CMD”) of a semiconductor device. In some embodiments, both the cut-conductive region layout patterns 271 and 272 are shifted along the Y direction to facilitate the interconnection features (not shown in FIG. 17A) connected to the conductive features corresponding to the conductive region layout patterns 251a or 251b. In some embodiments, the distance Li between the cut-conductive region layout pattern 271 and the active region layout pattern 222 (or 224) is different from the distance L2 between the cut-conductive region layout pattern 272 and the active region layout pattern 222 (or 224).

In this embodiment, the parts 206a and 206b collectively define or exhibit a unit 210k, which can repeat along the X direction, Y direction, or both. In this embodiment, the conductive region layout patterns 251a and 251b are fixed, which thereby facilitates the miniaturization of a semiconductor device.

Referring to FIG. 17B, it illustrates a perspective view of a semiconductor device 400 to which the layout 200k is applicable. The semiconductor device 400 may include, for example, a CFET device. FIG. 17B only illustrates a portion of the device, and it should be noted some features are omitted for brevity.

In some embodiments, the semiconductor device 400 includes active regions 422 and 424. Each of the active regions 422 and 424 extends along the X direction. The active region 424 is disposed at an elevation higher than that of the active region 422. In some embodiments, the active region 424 overlaps the active region 422 along the Z direction. In some embodiments, each of the active regions 422 and 424 may also be referred to as OD. In some embodiments, the layout pattern of the active regions 422 and 424 is the same as that of the active region layout patterns 222 and 224 as shown in FIG. 17A. Each of the active region 422 and 424 may function as an active region of an NMOS device or a PMOS device.

The semiconductor device 400 includes a gate stack 442. In some embodiments, the gate stack 442 extends along the Y direction and the Z direction. In some embodiments, the gate stack 442 includes a gate dielectric and a gate electrode. In some embodiments, the gate stack surrounds the active regions 422 and/or 424. In some embodiments, the layout pattern of the gate stack 442 is the same as that of the gate region layout pattern 242 as shown in FIG. 17A. In some embodiments, the gate stack 442 may also be referred to as “PO.”

The semiconductor device 400 includes dummy gates 444. In some embodiments, the dummy gate 444 extends along the Y direction and the Z direction. In some embodiments, the dummy gate 444 is a dielectric structure that includes one or more dielectric materials and functions as an electrical isolation structure. In some embodiments, the layout pattern of the dummy gate 444 is the same as that of the dummy gate region layout pattern 244 as shown in FIG. 17A. In some embodiments, the dummy gate 444 may also be referred to as “CPODE.”

The semiconductor device 400 includes conductive features 451a and 451b. Each of the conductive features 451a and 451b extends along the Y direction. The conductive feature 451b overlaps a corresponding conductive feature 451a along the Z direction. In some embodiments, the conductive features 451a and 451b are arranged as S/D contacts. In some embodiments, the conductive features 451a and 451b may also referred to as “MD.”

Although not shown in FIG. 17B, it should be noted that the semiconductor device 400 includes CPOs and CMDs that are configured to cut the gate stacks 442 and conductive features 451a (or 451b), respectively. In some embodiments, the CPO extends along the X direction and the Z direction. In some embodiments, the CMD extends along the X direction and the Z direction.

The semiconductor device 400 includes conductive lines 461, 462, and 463. Each of the conductive lines 461 to 463 is disposed under the active region 422. In some embodiments, each of the conductive lines 461 to 463 extends along the X direction. In some embodiments, each of the conductive lines 461 to 463 is configured to be electrically connected to the conductive feature 451a and/or gate stack 442. Each of the conductive lines 461 to 463 may function as a power grid (PG) conductor and/or be configured to transmit logic signals.

The semiconductor device 400 includes conductive lines 464, 465, and 466. Each of the conductive lines 464 to 466 is disposed above the active region 424. In some embodiments, each of the conductive lines 464 to 466 extends along the X direction. In some embodiments, each of the conductive lines 464 to 466 is configured to be electrically connected to the conductive feature 451b and/or gate stack 442. Each of the conductive lines 464 to 466 may function as a PG conductor and/or be configured to transmit logic signals.

The semiconductor device 400 includes interconnection features 471, 472, and 473. The interconnection feature 471 is configured to electrically connect the conductive line 461 (or 462 or 463) and the conductive feature 451a (or gate stack 442). The interconnection feature 472 is configured to electrically connect the conductive line 464 (or 465 or 466) and the conductive feature 451b (or gate stack 442). The interconnection feature 473 is configured to electrically connect the conductive features 451a and 451b.

In this embodiment, the layout patterns of the active regions, gate stacks, dummy gates, conductive features, and poly cut layers, are fixed, which facilitates miniaturization of the semiconductor device 400. Further, it should be noted that operation 170 can be followed by operations 120, 130, and/or 140 in other embodiments.

In some embodiments, the layout patterns not shown in regular layouts of each of the embodiments are determined after operations 110, 120, 130, 140, 150, 160, or 170. For example, the layout patterns of MD and/or CMD are determined after operations 110, 120, 130, 140, 150, or 160 and may not follow a regular arrangement.

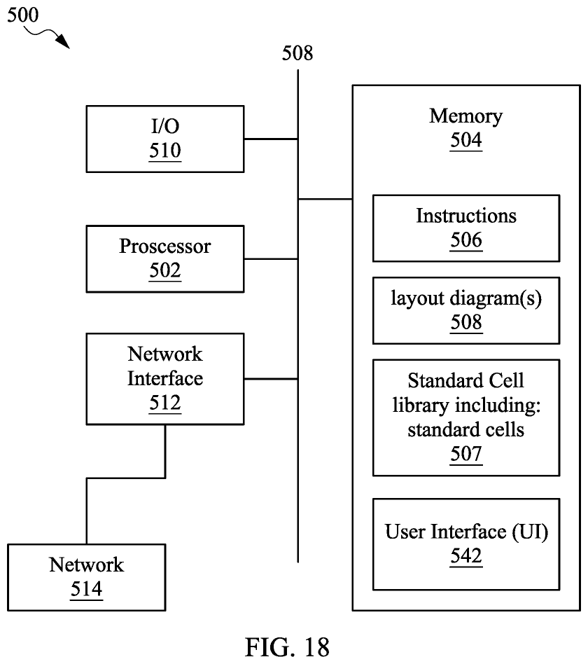

FIG. 18 is a block diagram of a system 500 of designing a semiconductor device, in accordance with some embodiments. The system 500 can include, for example, an electronic design automation (EDA) system.

In some embodiments, system 500 includes an automatic placement and routing (APR) system. Methods described herein of generating PG layout diagrams, in accordance with one or more embodiments, are implementable, for example, using the system 500, in accordance with some embodiments.

In some embodiments, system 500 is a general purpose computing device including a hardware processor 502 and a non-transitory, computer-readable storage medium 504. Storage medium 504, amongst other things, is encoded with, i.e., stores, computer program code 506, i.e., a set of executable instructions. Execution of instructions 506 by hardware processor 502 represents (at least in part) an EDA tool which implements a portion or all of a method according to an embodiment, e.g., the methods described herein in accordance with one or more embodiments (hereinafter, the noted processes and/or methods).

Processor 502 is electrically coupled to computer-readable storage medium 504 via a bus 508. Processor 502 is also electrically coupled to an I/O interface 510 by bus 508. A network interface 512 is also electrically connected to processor 502 via bus 508. Network interface 512 is connected to a network 514, so that processor 502 and computer-readable storage medium 504 are capable of connecting to external elements via network 514. Processor 502 is configured to execute computer program code 506 encoded in computer-readable storage medium 504 in order to cause system 500 to be usable for performing a portion or all of the noted processes and/or methods. In one or more embodiments, processor 502 is a central processing unit (CPU), a multi-processor, a distributed processing system, an application specific integrated circuit (ASIC), and/or a suitable processing unit.

In one or more embodiments, computer-readable storage medium 504 is an electronic, magnetic, optical, electromagnetic, infrared, and/or semiconductor system (or apparatus or device). For example, computer-readable storage medium 504 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 504 includes a compact disk-read only memory (CD-ROM), a compact disk-read/write (CD-R/W), and/or a digital video disc (DVD).

In one or more embodiments, storage medium 504 stores computer program code (instructions) 506 configured to cause system 500 (where such execution represents (at least in part) the EDA tool) to be usable for performing a portion or all of the noted processes and/or methods. In one or more embodiments, storage medium 504 also stores information which facilitates performing a portion or all of the noted processes and/or methods. In one or more embodiments, storage medium 504 stores library 507 of standard cells including such standard cells as disclosed herein and one or more layout diagrams 508 such as are disclosed herein.

System 500 includes I/O interface 510. I/O interface 510 is coupled to external circuitry. In one or more embodiments, I/O interface 510 includes a keyboard, keypad, mouse, trackball, trackpad, touchscreen, and/or cursor direction keys for communicating information and commands to processor 502.

System 500 also includes network interface 512 coupled to processor 502. Network interface 512 allows system 500 to communicate with network 514, to which one or more other computer systems are connected. Network interface 512 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 500.

System 500 is configured to receive information through I/O interface 510. The information received through I/O interface 510 includes one or more of instructions, data, design rules, libraries of standard cells, and/or other parameters for processing by processor 502. The information is transferred to processor 502 via bus 508. System 500 is configured to receive information related to a UI through I/O interface 510. The information is stored in computer-readable medium 504 as user interface (UI) 542.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods are implemented as a software application running on System 500. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

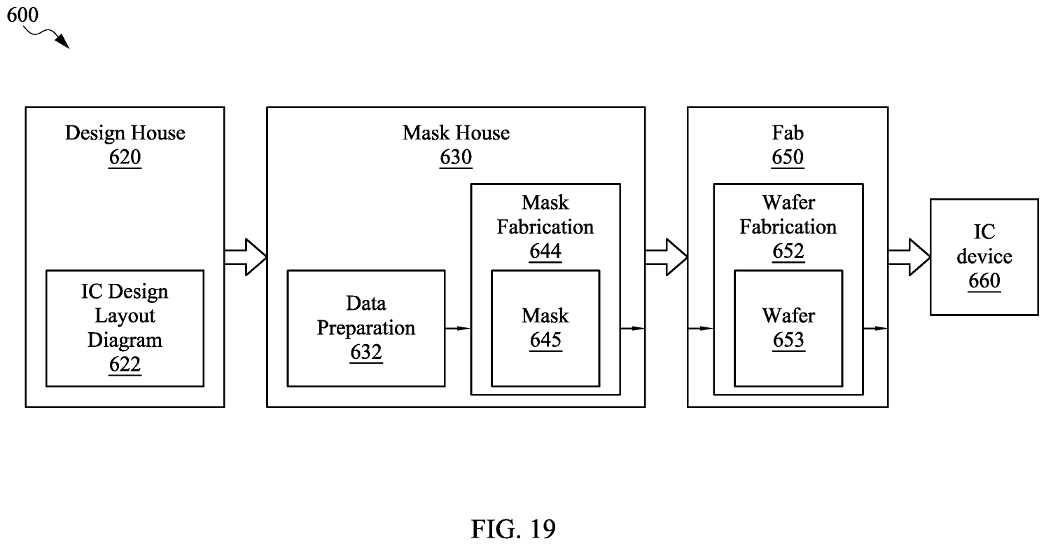

FIG. 19 is a block diagram of a semiconductor device manufacturing system 600, and a semiconductor device flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 600.

In FIG. 19, IC manufacturing system 600 includes entities, such as a design house 620, a mask house 630, and an IC manufacturer/fabricator (“fab”) 650, that interact with one another in the design, development, and manufacturing cycles and/or services related to manufacturing an IC device 660. The entities in system 600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 620, mask house 630, and IC fab 650 is owned by a single larger company. In some embodiments, two or more of design house 620, mask house 630, and IC fab 650 coexist in a common facility and use common resources.

Design house (or design team) 620 generates an IC design layout diagram 622. IC design layout diagram 622 includes various geometrical patterns designed for an IC device 660. The geometrical patterns correspond to patterns of metal, oxide, or semiconductor layers that make up the various components of IC device 660 to be fabricated. The various layers combine to form various IC features. For example, a portion of IC design layout diagram 622 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 620 implements a proper design procedure to form IC design layout diagram 622. The design procedure includes one or more of logic design, physical design or place and route. IC design layout diagram 622 is presented in one or more data files having information of the geometrical patterns. For example, IC design layout diagram 622 can be expressed in a GDSII file format or DFII file format.

Mask house 630 includes data preparation 632 and mask fabrication 644. Mask house 630 uses IC design layout diagram 622 to manufacture one or more masks 645 to be used for fabricating the various layers of IC device 660 according to IC design layout diagram 622. Mask house 630 performs mask data preparation 632, where IC design layout diagram 622 is translated into a representative data file (“RDF”). Mask data preparation 632 provides the RDF to mask fabrication 644. Mask fabrication 644 includes a mask writer. A mask writer converts the RDF to an image on a substrate, such as a mask (reticle) 645 or a semiconductor wafer 653. The design layout diagram 622 is manipulated by mask data preparation 632 to comply with particular characteristics of the mask writer and/or requirements of IC fab 650. In FIG. 19, mask data preparation 632 and mask fabrication 644 are illustrated as separate elements. In some embodiments, mask data preparation 632 and mask fabrication 644 can be collectively referred to as mask data preparation.

In some embodiments, mask data preparation 632 includes optical proximity correction (OPC) which uses lithography enhancement techniques to compensate for image errors, such as those that can arise from diffraction, interference, other process effects and the like. OPC adjusts IC design layout diagram 622. In some embodiments, mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 632 includes a mask rule checker (MRC) that checks the IC design layout diagram 622 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 622 to compensate for limitations during mask fabrication 644, which may undo part of the modifications performed by OPC in order to meet mask creation rules.

In some embodiments, mask data preparation 632 includes lithography process checking (LPC) that simulates processing that will be implemented by IC fab 650 to fabricate IC device 660. LPC simulates this processing based on IC design layout diagram 622 to create a simulated manufactured device, such as IC device 660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 622.

It should be understood that the foregoing description of mask data preparation 632 has been simplified for the purposes of clarity. In some embodiments, data preparation 632 includes additional features such as a logic operation (LOP) to modify the IC design layout diagram 622 according to manufacturing rules. Additionally, the processes applied to IC design layout diagram 622 during data preparation 632 may be executed in a variety of different orders.

After mask data preparation 632 and during mask fabrication 644, a mask 645 or a group of masks 645 are fabricated based on the modified IC design layout diagram 622. In some embodiments, mask fabrication 644 includes performing one or more lithographic exposures based on IC design layout diagram 622. In some embodiments, an electron-beam (e-beam) or a mechanism of multiple e-beams is used to form a pattern on a mask (photomask or reticle) 645 based on the modified IC design layout diagram 622. Mask 645 can be formed in various technologies. In some embodiments, mask 645 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 645 includes a transparent substrate (e.g., fused quartz) and an opaque material (e.g., chromium) coated in the opaque regions of the binary mask. In another example, mask 645 is formed using a phase shift technology. In a phase shift mask (PSM) version of mask 645, various features in the pattern formed on the phase shift mask are configured to have proper phase difference to enhance the resolution and imaging quality. In various examples, the phase shift mask can be attenuated PSM or alternating PSM. The masks generated by mask fabrication 644 are used in a variety of processes. For example, such a mask(s) can be used in an ion implantation process to form various doped regions in semiconductor wafer 653, in an etching process to form various etching regions in semiconductor wafer 653, and/or in other suitable processes.

IC fab 650 includes wafer fabrication 652. IC fab 650 is an IC fabricator that includes one or more manufacturing facilities for the fabrication of a variety of different IC products. In some embodiments, IC Fab 650 can be a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 650 uses mask(s) 645 fabricated by mask house 630 to fabricate IC device 660. Thus, IC fab 650 at least indirectly uses IC design layout diagram 622 to fabricate IC device 660. In some embodiments, semiconductor wafer 653 is fabricated by IC fab 650 using mask(s) 645 to form IC device 660. In some embodiments, the IC fabrication includes performing one or more lithographic exposures based at least indirectly on IC design layout diagram 622. Semiconductor wafer 653 includes a silicon substrate or other proper substrate having material layers formed thereon. Semiconductor wafer 653 further includes one or more of various doped regions, dielectric features, multilevel interconnects, and the like (formed at subsequent manufacturing steps).

Details regarding an integrated circuit (IC) manufacturing system (e.g., system 600 of FIG. 19), and an IC manufacturing flow associated therewith are found, e.g., in U.S. Pat. No. 9,256,709, granted Feb. 9, 2016, U.S. Pre-Grant Publication No. 20150278429, published Oct. 1, 2015, U.S. Pre-Grant Publication No. 20140040838, published Feb. 6, 2014, and U.S. Pat. No. 7,260,442, granted Aug. 21, 2007, the entireties of each of which are hereby incorporated by reference.

Some embodiments of the present disclosure provide a method of arranging patterns of a semiconductor device. The method includes: generating a plurality of active region layout patterns, wherein each of the plurality of active region layout patterns extends along a first direction; generating a plurality of gate region layout patterns, wherein each of the plurality of gate region layout patterns extends along a second direction different from the first direction and overlaps the plurality of active region layout patterns along a third direction different from the first direction and second direction; generating a plurality of dummy gate region layout patterns, wherein each of the plurality of dummy gate region layout patterns extends along the second direction and overlaps the plurality of active region layout patterns along the third direction, generating a plurality of cut feature layout patterns, wherein each of the plurality of cut feature layout patterns extends along the first direction and overlaps the plurality of gate region layout patterns and the plurality of dummy gate region layout patterns; and wherein the plurality of active region layout patterns, the plurality of cut feature layout patterns, the plurality of gate region layout pattern, and the plurality of dummy gate region layout patterns define or exhibit a plurality of units repeating periodically along at least one of the first direction, the second direction, or both.

Some embodiments of the present disclosure provide a system for arranging patterns of a semiconductor device. The system includes at least one processing unit and at least one memory including computer program code for one or more programs. The at least one memory, the computer program code and the at least one processing unit are configured to cause the system to perform: generating a plurality of gate region layout patterns, wherein each of the plurality of gate region layout patterns extends along a second direction different from the first direction and overlaps the plurality of active region layout patterns along a third direction different from the first direction and second direction; generating a plurality of dummy gate region layout patterns, wherein each of the plurality of dummy gate region layout patterns extends along the second direction and overlaps the plurality of active region layout patterns along the third direction, generating a plurality of cut feature layout patterns, wherein each of the plurality of cut feature layout patterns extends along the first direction and overlaps the plurality of gate region layout patterns and the plurality of dummy gate region layout patterns, and wherein the plurality of active region layout patterns, the plurality of cut feature layout patterns, the plurality of gate region layout pattern, and the plurality of dummy gate region layout patterns define or exhibit a plurality of units repeating periodically along at least one of the first direction, the second direction, or both.

Some embodiments of the present disclosure provide a method of arranging patterns of a semiconductor device. The method includes: generating a first active region layout pattern and a second active layout pattern, wherein each of the first active region layout pattern and the second active layout pattern extends along a first direction and are arranged along a second direction different from the first direction; generating a plurality of gate region layout patterns, wherein each of the plurality of gate region layout patterns extends along a third direction different from the first direction and the second direction, and each of the plurality of gate region layout patterns overlaps the first active region layout pattern and the second active layout pattern along the second direction; and generating a plurality of dummy gate region layout patterns, wherein each of the plurality of dummy gate region layout patterns extends along the third direction, and each of the plurality of dummy gate region layout patterns overlaps the first active region layout pattern and the second active layout pattern along the second direction, and wherein the first active region layout pattern, the second active layout pattern, the plurality of gate region layout pattern, and the plurality of dummy gate region layout patterns define or exhibit a plurality of units repeating periodically along at least one of the first direction, the third direction, or both.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of arranging patterns of a semiconductor device, the method comprising:
generating a plurality of active region layout patterns, wherein each of the plurality of active region layout patterns extends along a first direction;
generating a plurality of gate region layout patterns, wherein each of the plurality of gate region layout patterns extends along a second direction different from the first direction and overlaps the plurality of active region layout patterns along a third direction different from the first direction and second direction;
generating a plurality of dummy gate region layout patterns, wherein each of the plurality of dummy gate region layout patterns extends along the second direction and overlaps the plurality of active region layout patterns along the third direction,
generating a plurality of cut feature layout patterns, wherein each of the plurality of cut feature layout patterns extends along the first direction and overlaps the plurality of gate region layout patterns and the plurality of dummy gate region layout patterns,
and wherein the plurality of active region layout patterns, the plurality of cut feature layout patterns, the plurality of gate region layout pattern, and the plurality of dummy gate region layout patterns exhibit a plurality of units repeating periodically along at least one of the first direction, the second direction, or both.

2. The method of claim 1, further comprising:
removing the plurality of dummy gate region layout patterns; and
placing a plurality of active region break layout patterns overlapping the plurality of active region layout patterns, wherein each of the plurality of active region break layout patterns is configured to disconnect the plurality of active region layout patterns.

3. The method of claim 2, further comprising:
removing the plurality of cut feature layout patterns; and
cutting the plurality of gate region layout patterns to form a plurality of segments, wherein each of the plurality of segments overlaps two of the plurality of active region layout patterns.

4. The method of claim 1, further comprising:
reducing areas of the plurality of units.

5. The method of claim 4, wherein reducing areas of the plurality of units comprises:
reducing a dimension of each of the plurality of units along the first direction.

6. The method of claim 5, wherein reducing areas of the plurality of units comprises:
reducing a dimension of each of the plurality of units along the second direction.

7. The method of claim 1, further comprising:
determining a ratio of a quantity of the gate region layout patterns to a quantity of the dummy gate region layout patterns of one unit.

8. The method of claim 1, wherein the plurality of units comprises a first group arranging at an odd row and a second group arranging at an even row, and the method further comprises:
shifting the plurality of gate region layout patterns and the plurality of dummy gate layout patterns of the first group of the plurality of units along the first direction by a length between one of the plurality of gate region layout patterns and the plurality of dummy gate layout patterns which abut.

9. The method of claim 2, wherein the plurality of units comprises a first group arranging at an odd row and a second group arranging at an even row, and the method further comprises:
shifting the plurality of gate region layout patterns and the plurality of active region break layout patterns of the first group of the plurality of units along the first direction by a length equal to half of a pitch of the plurality of gate region layout patterns.

10. The method of claim 3, wherein the plurality of units comprises a first group arranging at an odd row and a second group arranging at an even row, and the method further comprises:
shifting the plurality of segments of the first group along the first direction by a length equal to half of a pitch of the plurality of gate region layout patterns.

11. A system for arranging patterns of a semiconductor device, comprising:
at least one processing unit; and
at least one memory including computer program code for one or more programs;
wherein the at least one memory, the computer program code and the at least one processing unit are configured to cause the system to perform:
generating a plurality of active region layout patterns, wherein each of the plurality of active region layout patterns extends along a first direction;
generating a plurality of gate region layout patterns, wherein each of the plurality of gate region layout patterns extends along a second direction different from the first direction and overlaps the plurality of active region layout patterns along a third direction different from the first direction and second direction;
generating a plurality of dummy gate region layout patterns, wherein each of the plurality of dummy gate region layout patterns extends along the second direction and overlaps the plurality of active region layout patterns along the third direction,
generating a plurality of cut feature layout patterns, wherein each of the plurality of cut feature layout patterns extends along the first direction and overlaps the plurality of gate region layout patterns and the plurality of dummy gate region layout patterns,
and wherein the plurality of active region layout patterns, the plurality of cut feature layout patterns, the plurality of gate region layout pattern, and the plurality of dummy gate region layout patterns exhibit a plurality of units repeating periodically along at least one of the first direction, the second direction, or both.

12. The system of claim 11, further comprising:
removing the plurality of dummy gate region layout patterns; and
placing a plurality of active region break layout patterns overlapping the plurality of active region layout patterns, wherein each of the plurality of active region break layout patterns is configured to disconnect the plurality of active region layout patterns.

13. The system of claim 12, further comprising:
removing the plurality of cut feature layout patterns; and
cutting the plurality of gate region layout patterns to form a plurality of segments, wherein each of the plurality of segments overlaps two of the plurality of active region layout patterns.

14. The system of claim 11, further comprising:
reducing areas of the plurality of units.

15. The system of claim 14, wherein reducing areas of the plurality of units comprises:
reducing a dimension of each of the plurality of units along the first direction.

16. The system of claim 15, wherein reducing areas of the plurality of units comprises:
reducing a dimension of each of the plurality of units along the second direction.

17. The system of claim 11, further comprising:
determining a ratio of a quantity of the gate region layout pattern to a quantity of the dummy gate region layout pattern of one unit.

18. The system of claim 11, wherein the plurality of units comprises a first group arranging at an odd row and a second group arranging at an even row, and the method further comprises:
shifting the plurality of gate region layout patterns and the plurality of dummy gate layout patterns of the first group of the plurality of units along the first direction by a length between one of the plurality of gate region layout patterns and the plurality of dummy gate layout patterns which abut.

19. A method of arranging patterns of a semiconductor device, the method comprising:
generating a first active region layout pattern and a second active layout pattern, wherein each of the first active region layout pattern and the second active layout pattern extends along a first direction and are arranged along a second direction different from the first direction;
generating a plurality of gate region layout patterns, wherein each of the plurality of gate region layout patterns extends along a third direction different from the first direction and the second direction, and each of the plurality of gate region layout patterns overlaps the first active region layout pattern and the second active layout pattern along the second direction; and
generating a plurality of dummy gate region layout patterns, wherein each of the plurality of dummy gate region layout patterns extends along the third direction, and each of the plurality of dummy gate region layout patterns overlaps the first active region layout pattern and the second active layout pattern along the second direction,
and wherein the first active region layout pattern, the second active layout pattern, the plurality of gate region layout pattern, and the plurality of dummy gate region layout patterns exhibit a plurality of units repeating periodically along at least one of the first direction, the third direction, or both.

20. The method of claim 19, wherein the first active region layout pattern is located at a first elevation and the second active region layout pattern is located at a second elevation different from the first direction along the second direction, and the method further comprises:
generating a plurality of first conductive region layout patterns, wherein each of the plurality of first conductive region layout patterns extends along the third direction, and each of the plurality of first conductive region layout patterns is located at the first elevation; and
generating a plurality of second conductive region layout patterns, wherein each of the plurality of first conductive region layout patterns extends along the third direction, and each of the plurality of first conductive region layout patterns is located at the second elevation,
and wherein the first active region layout pattern, the second active layout pattern, the plurality of gate region layout pattern, and the plurality of dummy gate region layout patterns, the plurality of first conductive region layout patterns, and the plurality of second conductive region layout patterns exhibit a plurality of units repeating periodically along at least one of the first direction, the third direction, or both.
